(19) United States
(12) Patent Application Publication
(10) Pub. No.: US 2018/0180501 A1
(43) Pub. Date: Jun. 28, 2018

(54) PRESSURE SENSOR, PRESSURE SENSOR MODULE, ELECTRONIC APPARATUS, AND VEHICLE

(71) Applicant: SEIKO EPSON CORPORATION, Tokyo (JP)

(72) Inventor: Takuya KINUGAWA, Suwa-shi (JP)

(73) Assignee: SEIKO EPSON CORPORATION, Tokyo (JP)

(21) Appl. No.: 15/842,159

(22) Filed: Dec. 14, 2017

(30) Foreign Application Priority Data
Dec. 27, 2016 (JP) 2016-252803

(51) Int. Cl. G01L 9/00; H01L 41/113; G01L 1/22; G01L 9/06; G01L 1/16

(52) U.S. Cl. CPC G01L 9/0054; H01L 41/1132; G01L 1/16; G01L 9/065; G01L 1/2281

(57) ABSTRACT

A pressure sensor includes a semiconductor substrate having a diaphragm that flexurally deforms by pressurization, a sensor part provided in the diaphragm, an insulating layer provided on the diaphragm, a conducting layer provided on the insulating layer, and a drive circuit that supplies a predetermined potential so that the drive voltage may be applied to the sensor part, wherein the conducting layer is set at a same potential as the predetermined potential or a potential larger than the predetermined potential.

### BACKGROUND

### 1. Technical Field

The present invention relates to a pressure sensor, pressure sensor module, electronic apparatus, and vehicle.

### 2. Related Art

In related art, as a pressure sensor, e.g. a configuration described in Patent Document 1 (JP-A-2001-281085) is known. The pressure sensor of Patent Document 1 has an N-type silicon substrate with a diaphragm that flexurally deforms by pressurization and a bridge circuit including piezoelectric resistance elements formed on the diaphragm, and is adapted to detect pressure using changes in resistance value of the piezoelectric resistance elements according to the flexure of the diaphragm.

In the pressure sensor of Patent Document 1, an insulating layer of a silicon oxide film (SiO2 film) is deposited on the upper surface of the diaphragm. By the silicon oxide film, the interface states of the piezoelectric resistance elements may be stabilized and noise generated in the detection signal may be reduced. Further, in the pressure sensor of Patent Document 1, a conducting layer of a polysilicon film (poly-Si film) is deposited on the silicon oxide film, and the sensor property is stabilized by connecting (grounding) the conducting layer to the ground.

However, in the configuration, when the silicon oxide film is thinner, P-type inversion layers are formed between the plurality of piezoelectric resistance elements of the N-type silicon substrate due to the field effect caused by the potential difference between the potential of the conducting layer (ground) and the drive voltage applied to the bridge circuit, and the piezoelectric resistance elements are short-circuited via the inversion layers.

Accordingly, in the pressure sensor of Patent Document 1, it is impossible to employ a thinner silicon oxide film. As a result, flexure of the diaphragm is harder and the sensor sensitivity is lower.

### SUMMARY

An advantage of some aspects of the invention is to provide a pressure sensor having an insulating layer that may be made thinner for improving sensor sensitivity, pressure sensor module, electronic apparatus, and vehicle.

The advantage can be achieved by the following configurations.

A pressure sensor according to an aspect of the invention includes a semiconductor substrate having a diaphragm that flexurally deforms by pressurization, a sensor part provided in the diaphragm, to which a drive voltage is applied, an insulating layer provided on the diaphragm, and a conducting layer provided on the insulating layer, wherein the conducting layer is set at a same potential as the drive voltage or a potential larger than the drive voltage.

With this configuration, formation of an inversion layer in the semiconductor substrate may be suppressed and short circuit of the sensor part may be suppressed. Accordingly, the thickness of the insulating layer may be reduced, and the diaphragm easily flexes by the amount of reduction and sensor sensitivity is improved.

In the pressure sensor according to the aspect of the invention, it is preferable that the semiconductor substrate contains silicon.

With this configuration, the semiconductor substrate easily handled in manufacturing and having excellent processing dimension precision is obtained.

In the pressure sensor according to the aspect of the invention, it is preferable that the conducting layer is electrically connected to the sensor part.

With this configuration, it is not necessary to prepare a circuit for applying a voltage to the conducting layer separately from the sensor part, and the apparatus configuration is simpler.

In the pressure sensor according to the aspect of the invention, it is preferable that the conducting layer contains polysilicon.

With this configuration, the conducting layer suitable for the manufacture using the semiconductor process is obtained.

In the pressure sensor according to the aspect of the invention, it is preferable that a thickness of the conducting layer is equal to or smaller than 50 nm.

With this configuration, the conducting layer may be made sufficiently thinner.

In the pressure sensor according to the aspect of the invention, it is preferable that the insulating layer contains silicon oxide.

With this configuration, the insulating layer suitable for the manufacture using the semiconductor process is obtained.

In the pressure sensor according to the aspect of the invention, it is preferable that a thickness of the insulating layer is equal to or smaller than 400 nm.

With this configuration, the insulating layer may be made sufficiently thinner.

In the pressure sensor according to the aspect of the invention, it is preferable that a pressure reference chamber located on the conducting layer side of the diaphragm is provided.

With this configuration, the pressure within the pressure reference chamber is a reference value of pressure detected by the pressure sensor. Accordingly, the pressure applied to the diaphragm may be detected more accurately.

In the pressure sensor according to the aspect of the invention, it is preferable that a pressure reference chamber located on an opposite side to the conducting layer of the diaphragm is provided.

With this configuration, the pressure within the pressure reference chamber is a reference value of pressure detected by the pressure sensor. Accordingly, the pressure applied to the diaphragm may be detected more accurately.

A pressure sensor module according to an aspect of the invention includes the pressure sensor according to the aspect of the invention and a package housing the pressure sensor.

With this configuration, the pressure sensor module with higher reliability that may enjoy the advantages of the pressure sensor according to the aspect of the invention is obtained.

An electronic apparatus according to an aspect of the invention includes the pressure sensor according to the aspect of the invention.

With this configuration, the electronic apparatus with higher reliability that may enjoy the advantages of the pressure sensor according to the aspect of the invention is obtained.

A vehicle according to an aspect of the invention includes the pressure sensor according to the aspect of the invention.

With this configuration, the vehicle with higher reliability that may enjoy the advantages of the pressure sensor according to the aspect of the invention is obtained.

### BRIEF DESCRIPTION OF THE DRAWINGS

The invention will be described with reference to the accompanying drawings, wherein like numbers reference like elements.

FIG. 1 is a sectional view of a pressure sensor according to a first embodiment of the invention.

FIG. 2 is a plan view showing a sensor part of the pressure sensor shown in FIG. 1.

FIG. 3 shows a bridge circuit containing the sensor part shown in FIG. 2.

FIG. 4 is a partially enlarged sectional view of a diaphragm of the pressure sensor shown in FIG. 1.

FIG. 5 is a flowchart showing a manufacturing method of the pressure sensor shown in FIG. 1.

FIG. 6 is a sectional view for explanation of the manufacturing method of the pressure sensor shown in FIG. 1.

FIG. 7 is a sectional view for explanation of the manufacturing method of the pressure sensor shown in FIG. 1.

FIG. 8 is a sectional view for explanation of the manufacturing method of the pressure sensor shown in FIG. 1.

FIG. 9 is a sectional view for explanation of the manufacturing method of the pressure sensor shown in FIG. 1.

FIG. 10 is a sectional view for explanation of the manufacturing method of the pressure sensor shown in FIG. 1.

FIG. 11 is a sectional view for explanation of the manufacturing method of the pressure sensor shown in FIG. 1.

FIG. 12 is a sectional view for explanation of the manufacturing method of the pressure sensor shown in FIG. 1.

FIG. 13 is a sectional view for explanation of the manufacturing method of the pressure sensor shown in FIG. 1.

FIG. 14 is a sectional view for explanation of the manufacturing method of the pressure sensor shown in FIG. 1.

FIG. 15 is a sectional view for explanation of the manufacturing method of the pressure sensor shown in FIG. 1.

FIG. 16 is a sectional view of a pressure sensor according to a second embodiment of the invention.

FIG. 17 is a sectional view of a pressure sensor according to a third embodiment of the invention.

FIG. 18 is a sectional view of a pressure sensor according to a fourth embodiment of the invention.

FIG. 19 is a sectional view of a pressure sensor module according to a fifth embodiment of the invention.

FIG. 20 is a plan view of a supporting substrate of the pressure sensor module shown in FIG. 19.

FIG. 21 is a perspective view showing an altimeter as an electronic apparatus according to a sixth embodiment of the invention.

FIG. 22 is a front view showing a navigation system as an electronic apparatus according to a seventh embodiment of the invention.

FIG. 23 is a perspective view showing an automobile as a vehicle according to an eighth embodiment of the invention.

### DESCRIPTION OF EXEMPLARY EMBODIMENTS

As below, a pressure sensor, pressure sensor module, electronic apparatus, and vehicle according to the invention will be explained in detail based on embodiments shown in the accompanying drawings.

### First Embodiment

First, a pressure sensor according to the first embodiment of the invention will be explained.

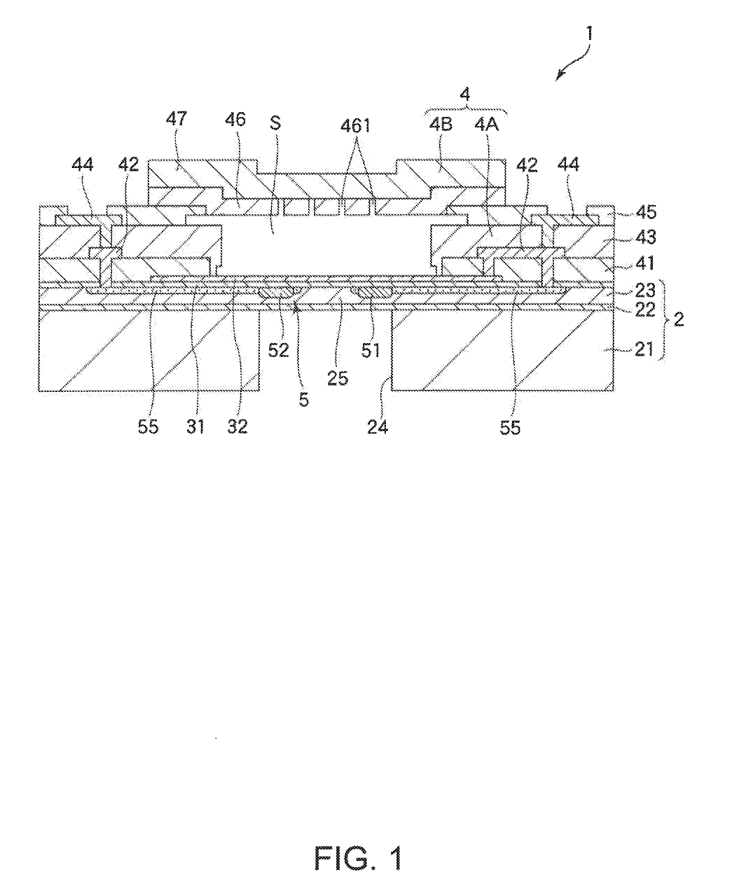

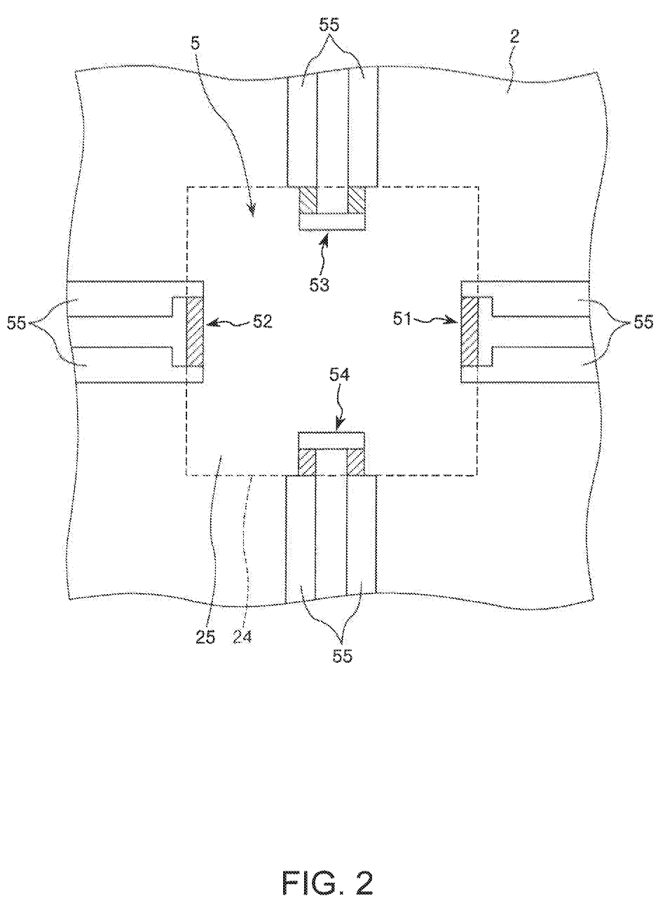

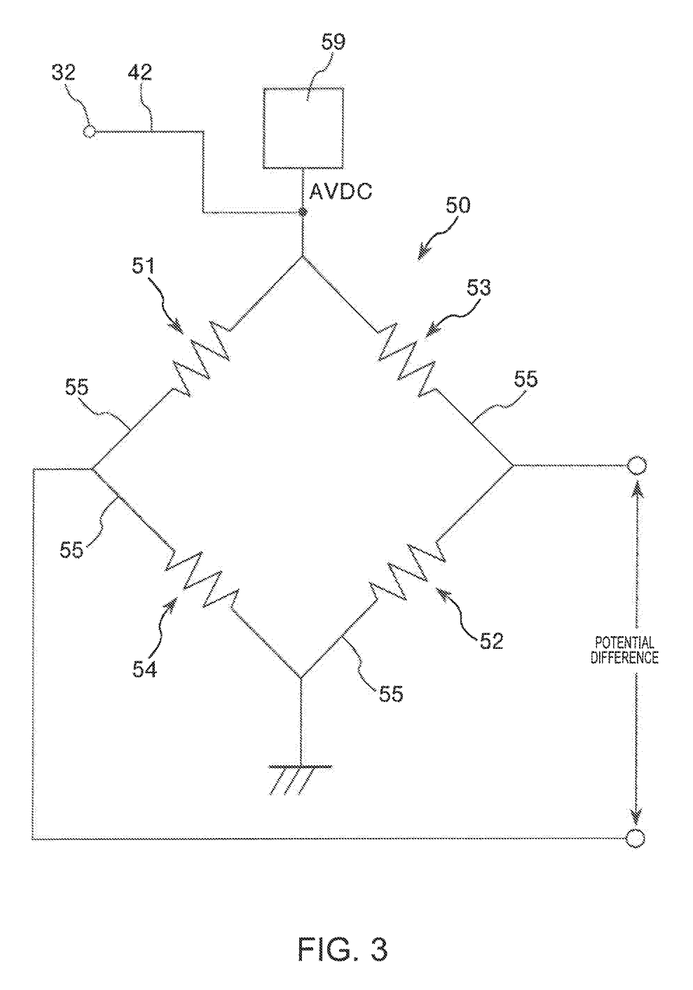

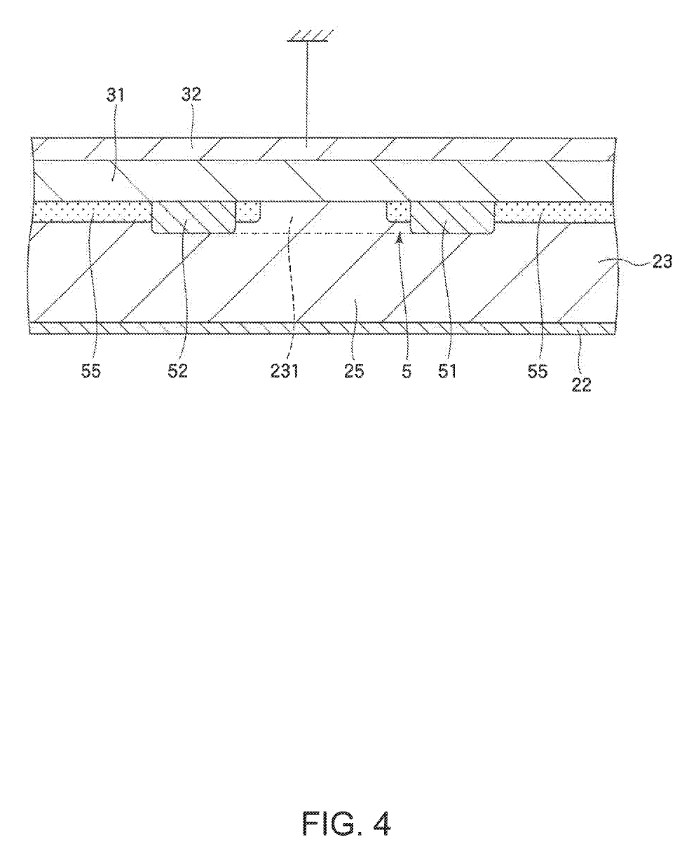

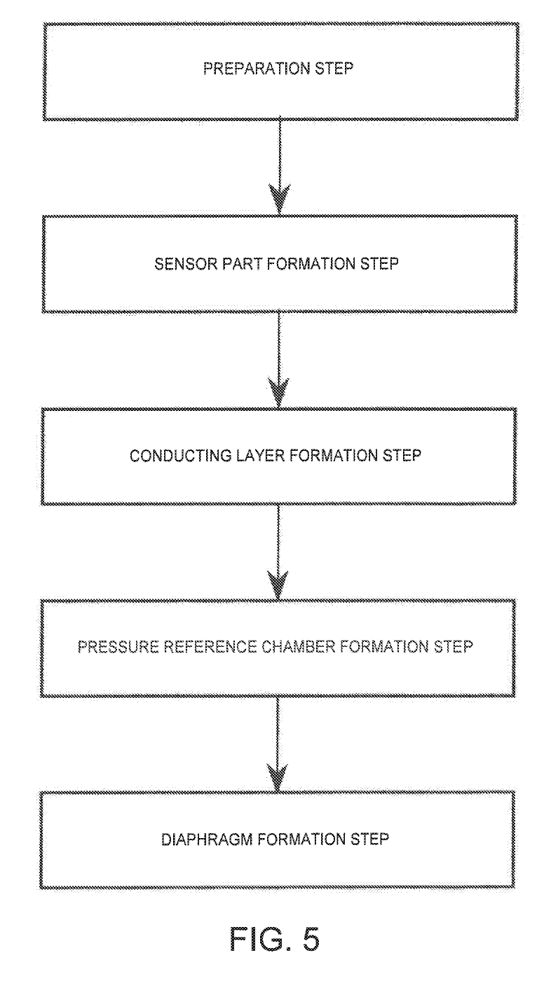

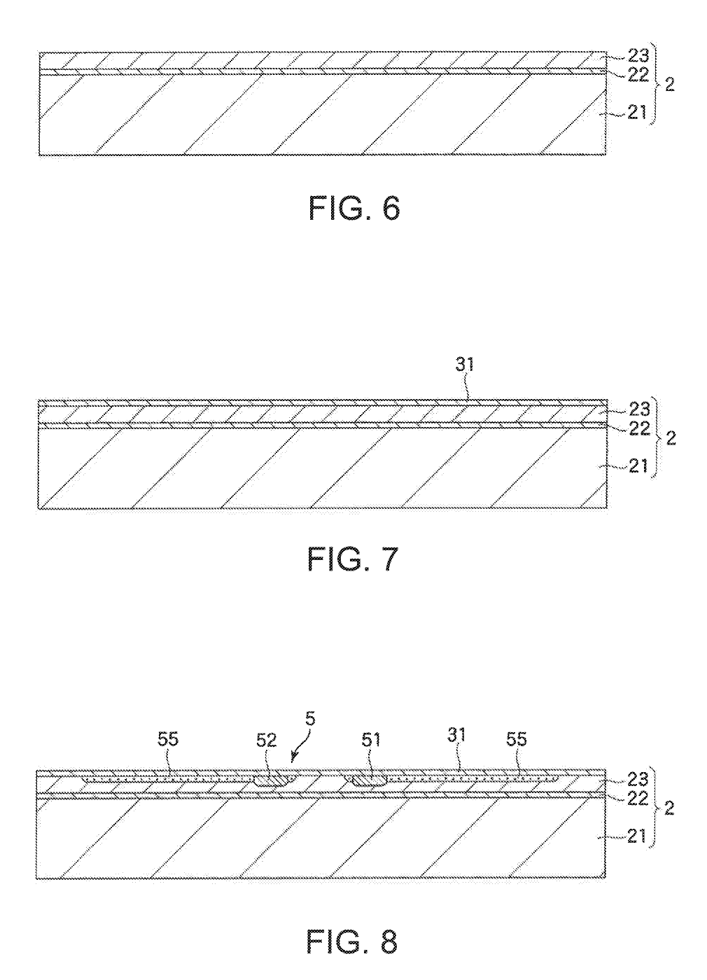

FIG. 1 is a sectional view of the pressure sensor according to the first embodiment of the invention. FIG. 2 is a plan view showing a sensor part of the pressure sensor shown in FIG. 1. FIG. 3 shows a bridge circuit containing the sensor part shown in FIG. 2. FIG. 4 is a partially enlarged sectional view of a diaphragm of the pressure sensor shown in FIG. 1. FIG. 5 is a flowchart showing a manufacturing method of the pressure sensor shown in FIG. 1. FIGS. 6 to 15 are respectively sectional views for explanation of the manufacturing method of the pressure sensor shown in FIG. 1. Note that, in the following explanation, the upside in FIGS. 1, 4, 6 to 15 is also referred to as “upper” and the downside is also referred to as “lower”. Further, a plan view of a semiconductor substrate, i.e., a plan view as seen from the upside or downside in FIG. 1 is also simply referred to as “plan view”.

A pressure sensor 1 shown in FIG. 1 includes a semiconductor substrate 2 having a diaphragm 25 that flexurally deforms by pressurization, an insulating layer 31 and a conducting layer 32 provided on the upper surface of the semiconductor substrate 2, a pressure reference chamber S provided on the upper surface side of the diaphragm 25, a surrounding structure 4 forming the pressure reference chamber S with the semiconductor substrate 2, and a sensor part 5 provided on the upper surface side of the diaphragm 25.

As shown in FIG. 1, the semiconductor substrate 2 is formed by an SOI substrate having a first silicon layer 21, a second silicon layer 23 provided on the upside of the first silicon layer 21, and a silicon oxide layer 22 provided between the first, second silicon layers 21, 23. That is, the semiconductor substrate 2 contains silicon. Thereby, the semiconductor substrate 2 easily handled in manufacturing and having excellent processing dimension precision is obtained.

Note that, in the embodiment, the first, second silicon layers 21, 23 are respectively N-type silicon layers. Note that the semiconductor substrate 2 is not particularly limited, but e.g. P-type silicon layers may be used as the first, second silicon layers 21, 23. Or, the semiconductor substrate 2 is not particularly limited to the SOI substrate, but, e.g. a single-layer silicon substrate may be used. Or, the semiconductor substrate 2 may be a substrate formed using another semiconductor material than silicon e.g. germanium, gallium arsenide, gallium arsenide phosphide, gallium nitride, silicon carbide, or the like.

In the semiconductor substrate 2, the diaphragm 25 having a smaller thickness than the surrounding part and flexurally deforming by pressurization is provided. In the semiconductor substrate 2, a recessed portion 24 having a bottom opening downward is formed, and the upside of the recessed portion 24 (the part in which the semiconductor substrate 2 is thinner due to the recessed portion 24) is the diaphragm 25. The lower surface of the diaphragm 25 is a pressure receiving surface that receives pressure. The recessed portion 24 is a space (cavity portion) for forming the pressure reference chamber S, which will be described later, formed on the opposite side to the pressure receiving surface of the diaphragm 25. Note that, in the embodiment, the shape in the plan view of the diaphragm 25 is a nearly square shape, however, the shape in the plan view of the diaphragm 25 is not particularly limited, but may be e.g. a circular shape.

Here, in the embodiment, the recessed portion 24 is formed by dry etching using a silicon deep etching apparatus. Specifically, steps of isotropic etching, protective film deposition, and anisotropic etching are repeated from the lower surface side of the semiconductor substrate 2, the first silicon layer 21 is dug, and thereby, the recessed portion 24 is formed. The steps are repeated and, when etching reaches the silicon oxide layer 22, the etching ends at the silicon oxide layer 22 as an etching stopper, and thereby, the recessed portion 24 is obtained. According to the forming method, the inner wall side surfaces of the concave portion 24 are nearly perpendicular to the principal surface of the semiconductor substrate 2, and thereby, the opening area of the recessed portion 24 may be made smaller. Accordingly, reduction of the mechanical strength of the semiconductor substrate 2 may be suppressed and upsizing of the pressure sensor 1 may be suppressed. Note that periodical concavities and convexities (not shown) are formed on the inner wall side surfaces of the recessed portion 24 in the digging direction by the repetition of the above described steps.

The forming method of the recessed portion 24 is not limited to the above described method, but e.g. wet etching may be used for the formation. Further, in the embodiment, the silicon oxide layer 22 is left on the lower surface side of the diaphragm 25, however, the silicon oxide layer 22 may be further removed. That is, the diaphragm 25 may be formed by a single layer of the second silicon layer 23. Thereby, the diaphragm 25 may be made thinner and the diaphragm 25 that flexurally deforms more easily is obtained. Further, in the case where the diaphragm 25 includes the plurality of layers (silicon oxide layer 22 and second silicon layer 23) as the embodiment, thermal stress due to differences in coefficient of thermal expansion of the respective layers is generated and the diaphragm 25 may flexurally deform unintentionally, i.e., due to another force than pressure as a subject to be detected. On the other hand, the diaphragm 25 is formed by the single layer, and thereby, the above described thermal stress is not generated and the pressure as the subject to be detected may be detected more accurately.

The thickness of the diaphragm 25 is not particularly limited and different depending on the size of the diaphragm 25 or the like, but preferably from 1 μm to 10 μm and more preferably from 1 μm to 3 μm when the width of the diaphragm 25 is from 100 m to 150 μm, for example. The thickness is set as above, and thereby, the diaphragm 25 having a sufficiently small thickness and easily flexurally deforming by pressurization is obtained with the sufficient mechanical strength kept.

In the diaphragm 25, the sensor part 5 that may detect pressure acting on the diaphragm 25 is provided. Further, the sensor part 5 is driven by application of a drive voltage AVDC as will be described later. As shown in FIG. 2, the sensor part 5 has four piezoelectric resistance elements 51, 52, 53, 54 provided in the diaphragm 25. Further, the piezoelectric resistance elements 51, 52, 53, 54 are electrically connected to one another via wires 55 and form a bridge circuit 50 (Wheatstone bridge circuit) shown in FIG. 3. A drive circuit 59 that supplies (applies) the drive voltage AVDC is connected to the bridge circuit 50. The bridge circuit 50 outputs a detection signal (voltage) according to the changes in resistance value of the piezoelectric resistance elements 51, 52, 53, 54 based on the flexure of the diaphragm 25. Accordingly, the pressure on the diaphragm 25 may be detected based on the output detection signal.

Particularly, the piezoelectric resistance elements 51, 52, 53, 54 are arranged in the outer edge portion of the diaphragm 25. When the diaphragm 25 flexurally deforms by pressurization, large stress is applied particularly to the outer edge portion of the diaphragm 25. The piezoelectric resistance elements 51, 52, 53, 54 are provided in the outer edge portion, and thereby, the above described detection signal may be increased and pressure detection sensitivity is improved. Note that the arrangement of the piezoelectric resistance elements 51, 52, 53, 54 is not particularly limited, but the piezoelectric resistance elements 51, 52, 53, 54 may be provided over the outer edge of the diaphragm 25, for example.

Each of the piezoelectric resistance elements 51, 52, 53, 54 is formed by doping (diffusion or implantation) of an impurity such as phosphorus or boron in the second silicon layer 23 of the semiconductor substrate 2, for example. Further, the wires 55 are formed by doping (diffusion or implantation) of an impurity such as phosphorus or boron in the second silicon layer 23 of the semiconductor substrate 2 at a higher concentration than that of the piezoelectric resistance elements 51, 52, 53, 54.

The configuration of the sensor part 5 is not particularly limited as long as the part may detect the pressure on the diaphragm 25. For example, at least one piezoelectric resistance element that does not form the bridge circuit 50 may be provided in the diaphragm 25.

As shown in FIG. 1, the insulating layer 31 and the conducting layer 32 are deposited on the upper surface of the semiconductor substrate 2. More specifically, the insulating layer 31 is deposited (provided) on the upper surface of the semiconductor substrate 2, and the conducting layer 32 is deposited (provided) on the upper surface of the insulating layer 31. The insulating layer 31 and the conducting layer 32 are provided to overlap with the entire area of the diaphragm 25 in the plan view of the semiconductor substrate 2.

The insulating layer 31 is formed by a silicon oxide film (SiO2 film). That is, the insulating layer 31 contains silicon oxide. As described above, the insulating layer 31 is formed by the silicon oxide film, and thereby, the interface states of the piezoelectric resistance elements 51, 52, 53, 54 of the sensor part 5, which will be described later, may be reduced and generation of noise may be suppressed. Further, the insulating layer 31 is formed by the silicon oxide film, and thereby, the insulating layer 31 suitable for the manufacture using the semiconductor process, i.e., easily formed and having little restriction (particularly, thermal restriction) on the subsequent manufacturing process is obtained.

The conducting layer 32 is formed by a polysilicon film (Poly-Si film). That is, the conducting layer 32 contains polysilicon. As described above, the conducting layer 32 is formed by the polysilicon film, and thereby, the conducting layer 32 suitable for the manufacture using the semiconductor process, i.e., easily formed and having little restriction (particularly, thermal restriction) on the subsequent manufacturing process is obtained.

Further, as shown in FIGS. 1 and 3, the conducting layer 32 is electrically connected to the drive circuit 59 that supplies the drive voltage AVDC to the bridge circuit 50 via a wiring layer 42. That is, the conducting layer 32 is set at the same potential as the drive voltage applied to the bridge circuit 50 (sensor part 5). Thereby, the following advantages may be offered.

As shown in FIG. 4, as in related art (the above described Patent Document 1), when the conducting layer 32 is connected (grounded) to the ground, if the insulating layer 31 is thinner, a P-type inversion layer 231 is formed in the second silicon layer 23 (N-type silicon layer) due to the field effect caused by the potential difference between the potential of the conducting layer 32 (ground potential) and the drive voltage AVDC applied to the bridge circuit 50, and the sensor part 5 is short-circuited via the inversion layer 231. Accordingly, in related art, it is impossible to reduce the thickness of the insulating layer 31.

On the other hand, as described above, in the embodiment, the conducting layer 32 is set at the same potential as the drive voltage applied to the bridge circuit 50. Accordingly, the P-type inversion layer 231 as in related art is not formed or short circuit of the sensor part 5 via the inversion layer 231 does not occur. Therefore, the insulating layer 31 can be made thinner than that in related art. Accordingly, the insulating layer 31 may be made sufficiently thinner, and difficulty in flexure of the diaphragm 25 may be reduced by the insulating layer 31.

The above described conducting layer 32 is electrically connected to the sensor part 5. Thereby, the drive voltage AVDC may be also applied to the conducting layer 32 from the drive circuit 59 for the sensor part 5, and the conducting layer 32 may be set at the same potential as the drive voltage AVDC by the simple configuration. Further, it is not necessary to provide a circuit for applying a voltage to the conducting layer 32 separately from the drive circuit 59 for the sensor part 5, and the apparatus configuration is simpler. Particularly, in the embodiment, the conducting layer 32 is electrically connected to the sensor part 5 within the surrounding structure 4 as will be described later. Thereby, the conducting layer 32 may be electrically connected to the sensor part 5 more easily.

Note that the thickness of the insulating layer 31 is not particularly limited, but varies depending on the thickness of the diaphragm 25. For example, when the thickness of the diaphragm 25 is from 1 μm to 10 μm, the thickness is preferably equal to or smaller than 400 nm and more preferably equal to or smaller than 300 nm. Thereby, the insulating layer 31 may be made sufficiently thinner for the diaphragm 25 and the difficulty in flexure of the diaphragm 25 may be reduced by the insulating layer 31. The minimum value of the thickness of the insulating layer 31 is not particularly limited, but preferably 50 nm and more preferably 100 nm, for example. Thereby, the above described advantages (the advantages of reduction of the interface states of the piezoelectric resistance elements 51, 52, 53, 54) may be offered more reliably.

Further, the thickness of the conducting layer 32 is not particularly limited, but varies depending on the thickness of the diaphragm 25. For example, when the thickness of the diaphragm 25 is from 1 μm to 10 μm, the thickness is preferably equal to or smaller than 50 nm and more preferably equal to or smaller than 30 nm. Thereby, the conducting layer 32 may be made sufficiently thinner for the diaphragm 25 and the difficulty in flexure of the diaphragm 25 may be reduced by the conducting layer 32. The minimum value of the thickness of the conducting layer 32 is not particularly limited, but preferably 5 nm and more preferably 10 nm, for example. Thereby, breakage of the conducting layer 32 may be suppressed. Further, an excessive increase of the resistance value of the conducting layer 32 may be suppressed and, for example, an excessive temperature rise of the conducting layer 32 may be suppressed. Accordingly, unintended flexural deformation of the diaphragm 25 due to thermal stress (stress caused by the difference in coefficient of thermal expansion between the diaphragm 25 and the conducting layer 32) may be suppressed, and the applied pressure may be detected more accurately.

The total of the thicknesses (total thickness) of the insulating layer 31 and the conducting layer 32 is not particularly limited, but preferably equal to or smaller than one tenth and more preferably equal to or smaller than one hundredth of the thickness of the diaphragm 25. Thereby, the stacked structure of the insulating layer 31 and the conducting layer 32 may be made sufficiently thinner.

The insulating layer 31 and the conducting layer 32 are made thinner, and thereby, the above described difficulty in flexure of the diaphragm 25 may be reduced and the following advantages may be offered. In the embodiment, the insulating layer 31 and the conducting layer 32 are stacked on the diaphragm 25, and it is considered that the diaphragm 25 and the stacked structure of the insulating layer 31 and the conducting layer 32 function as “diaphragm” that flexurally deforms by pressurization. In a discussion of the diaphragm in the thickness direction, stress generated when the diaphragm flexurally deforms by pressurization is larger from the center part in the thickness direction toward the surfaces (upper surface and lower surface). Accordingly, the piezoelectric resistance elements 51, 52, 53, 54 are provided closer to the upper surface or lower surface of the diaphragm, and thereby, even when the same pressure is applied, a larger detection signal is obtained. From the viewpoint, as described above, the insulating layer 31 and the conducting layer 32 are made thinner, and thereby, the piezoelectric resistance elements 51, 52, 53, 54 may be provided closer to the upper surface of the diaphragm, a larger detection signal is obtained, and pressure detection accuracy is further improved.

As above, the insulating layer 31 and the conducting layer 32 are explained. In the embodiment, the insulating layer 31 is formed by the silicon oxide film, however, the configuration of the insulating layer 31 is not particularly limited as long as the layer has an insulation property, but e.g. a silicon nitride film (SiNx film), silicon oxynitride film (SiON film), or the like may be used. Or, the insulating layer 31 may include a stacked structure of a plurality of layers formed by different materials. In the embodiment, the conducting layer 32 is formed by the polysilicon film, however, the configuration of the conducting layer 32 is not particularly limited as long as the layer has conductivity, but e.g. a metal material such as aluminum may be used. Further, in the embodiment, the conducting layer 32 is stacked on the insulating layer 31, however, at least one different layer may intervene between the layers.

As shown in FIG. 1, the pressure reference chamber S is provided on the upside of the diaphragm 25. That is, the pressure sensor 1 has the pressure reference chamber S located on the conducting layer 32 side of the diaphragm 25. The pressure reference chamber S is formed by being surrounded by the semiconductor substrate 2 and the surrounding structure 4. The pressure reference chamber S is an airtight space and the pressure within the pressure reference chamber S is a reference value of pressure detected by the pressure sensor 1. Accordingly, the pressure applied to the diaphragm 25 may be detected more accurately.

Particularly, it is preferable that the pressure reference chamber S is in a vacuum state (e.g. at about 10 Pa or less). Thereby, the pressure sensor 1 may be used as “absolute pressure sensor” that detects pressure with reference to vacuum, and the pressure sensor 1 with higher convenience is obtained. Note that the pressure reference chamber S is not necessarily in the vacuum state as long as it is kept at constant pressure.

As shown in FIG. 1, the surrounding structure 4 has a side wall portion 4A in a frame shape surrounding the pressure reference chamber S in the plan view of the semiconductor substrate 2 and a lid portion 4B closing the opening of the side wall portion on the upper surface side of the semiconductor substrate 2. The surrounding structure 4 has an interlayer insulating film 41 provided on the semiconductor substrate 2, the wiring layer 42 provided on the interlayer insulating film 41, an interlayer insulating film 43 provided on the wiring layer 42 and the interlayer insulating film 41, a wiring layer 44 provided on the interlayer insulating film 43, a surface protective film 45 provided on the wiring layer 44 and the interlayer insulating film 43, a covering layer 46 provided on the surface protective film 45, and a sealing layer 47 provided on the covering layer 46.

The interlayer insulating films 41, 43 are provided in frame shapes to surround the pressure reference chamber S in the plan view. As the interlayer insulating films 41, 43, e.g. insulating films such as silicon oxide films (SiO2) may be used.

The wiring layers 42, 44 are provided on the interlayer insulating films 41, 43 to penetrate the interlayer insulating films 41, 43 and electrically connected to the wires 55 of the sensor part 5. The wires 55 are led out to the upper surface of the surrounding structure 4 via the wiring layers 42, 44. As the wiring layers 42, 44, e.g. metal films such as aluminum films may be used.

Here, as described above, the sensor part 5 and the conducting layer 32 are electrically connected by the wiring layer 42. Thereby, the conducting layer 32 may be electrically connected to the sensor part 5 within the surrounding structure 4 and the electrical connection is made more easily.

The surface protective film 45 has a function of protecting the surrounding structure 4 from moisture, dirt, scratches, etc. The surface protective film 45 is not particularly limited, but e.g. a silicon oxide film, silicon nitride film, polyimide film, epoxy resin film, or the like may be used. Note that, in the embodiment, a stacked structure of a silicon oxide film and a silicon nitride film is used.

The covering layer 46 is provided to cover the upper opening of the side wall portion 4A. The ceiling part of the pressure reference chamber S of the covering layer 46 is the lid portion 4B. Further, the covering layer 46 has a plurality of through holes 461 communicated with inside and outside of the pressure reference chamber S. These through holes 461 are holes for release etching for removing a sacrifice layer filling the pressure reference chamber S as will be explained in a manufacturing method to be described later. The covering layer 46 is not particularly limited, but may be formed using e.g. silicon.

The sealing layer 47 is provided on the upper surface of the covering layer 46 and the through holes 461 are sealed by the sealing layer 47. The sealing layer 47 is not particularly limited, but may be formed using e.g. silicon. Or, the covering layer 46 may be formed by a stacked structure in which a plurality of layers are stacked.

As above, the configuration of the pressure sensor 1 is explained. As described above, the pressure sensor 1 includes the semiconductor substrate 2 having the diaphragm 25 that flexurally deforms by pressurization, the sensor part 5 provided in the diaphragm 25, to which the drive voltage AVDC is applied, the insulating layer 31 provided on the diaphragm 25, and the conducting layer 32 provided on the insulating layer 31. Further, the conducting layer 32 is set at the same potential as the drive voltage AVDC applied to the sensor part 5. Thereby, as described above, formation of an inversion layer in the semiconductor substrate 2 may be suppressed and short circuit of the sensor part 5 may be suppressed. Accordingly, the thickness of the insulating layer 31 may be reduced, and the diaphragm 25 easily flexes by the amount of reduction and the sensor sensitivity is improved. The potential of the conducting layer 32 is fixed, and thereby, the influence of disturbance on the sensor part 5 may be reduced and pressure may be detected more accurately.

Note that, in the embodiment, the configuration in which the conducting layer 32 is electrically connected to the sensor part 5 and the drive voltage AVDC is applied to the conducting layer 32 is explained, however, the configuration of the pressure sensor 1 is not limited to that. For example, a configuration having an amplifier circuit (not shown) provided within the pressure sensor 1 and amplifying the drive voltage AVDC in which a voltage larger than the drive voltage AVDC, is applied to the conducting layer 32 may be employed. That is, the conducting layer 32 may be set at a potential larger than the drive voltage AVDC applied to the sensor part 5. According to the configuration, the same advantages as those of the above described pressure sensor 1 of the embodiment may be offered.

Next, a manufacturing method of the pressure sensor 1 will be explained. As shown in FIG. 5, the manufacturing method of the pressure sensor 1 includes a preparation step of preparing the semiconductor substrate 2, a sensor part formation step of forming the sensor part 5 in the semiconductor substrate 2, a conducting layer formation step of forming the conducting layer 32 on the upper surface of the semiconductor substrate 2, a pressure reference chamber formation step of forming the pressure reference chamber S on the upside of the semiconductor substrate 2, and a diaphragm formation step of forming the diaphragm 25 in the semiconductor substrate 2.

### Preparation Step

First, as shown in FIG. 6, the semiconductor substrate 2 of the N-type SOI substrate in which the first silicon layer 21, the silicon oxide layer 22, and the second silicon layer 23 are stacked is prepared. Then, as shown in FIG. 7, the surface of the second silicon layer 23 is thermally oxidized, and thereby, the insulating layer 31 made of the silicon oxide film is formed.

### Sensor Part Formation Step

Then, as shown in FIG. 8, an impurity such as phosphorus or boron is implanted into the surface of the second silicon layer 23, and thereby, the sensor part 5 is formed.

### Conducting Layer Formation Step

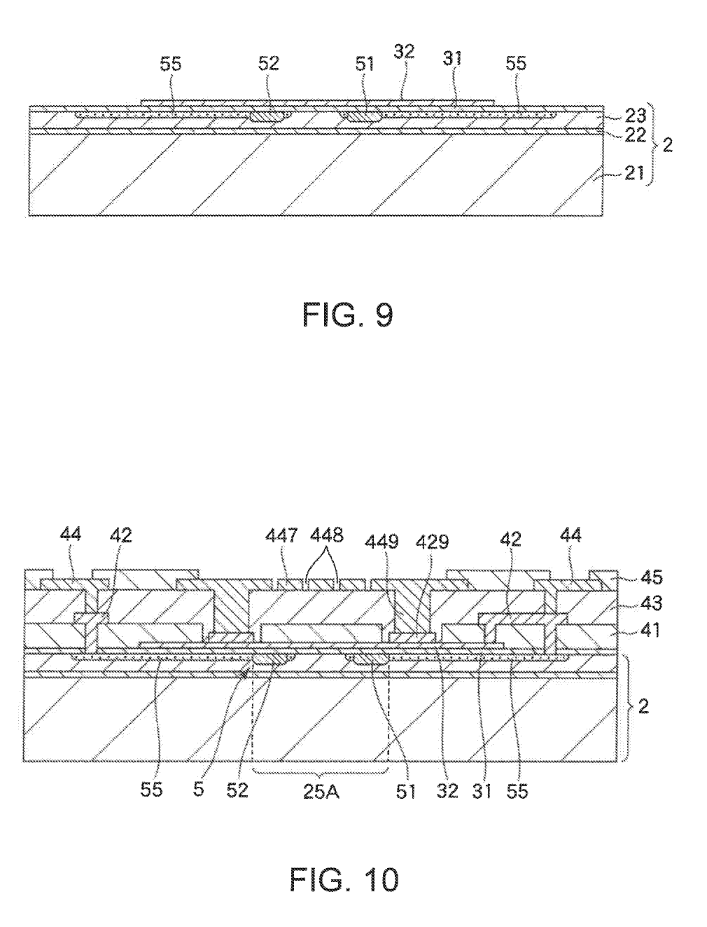

Then, as shown in FIG. 9, the conducting layer 32 of the polysilicon film made is formed using sputtering, CVD, or the like.

### Pressure Reference Chamber Formation Step

Then, as shown in FIG. 10, the interlayer insulating film 41, the wiring layer 42, the interlayer insulating film 43, the wiring layer 44, and the surface protective film 45 are sequentially formed on the semiconductor substrate 2 using sputtering, CVD, or the like. Note that, in the embodiment, the interlayer insulating films 41, 43 are formed by silicon oxide films and the wiring layers 42, 44 are formed by aluminum films. Further, the wiring layer 42 has a guard ring 429 in a frame shape surrounding a region 25A to be the diaphragm 25 in the plan view. Furthermore, the wiring layer 44 has a guard ring 449 in a frame shape surrounding the region 25A and connected to the guard ring 429 and a ceiling portion 447 facing the region 25A and covering the opening of the guard ring 449 in the plan view, and a plurality of through holes 448 are formed in the ceiling portion 447.

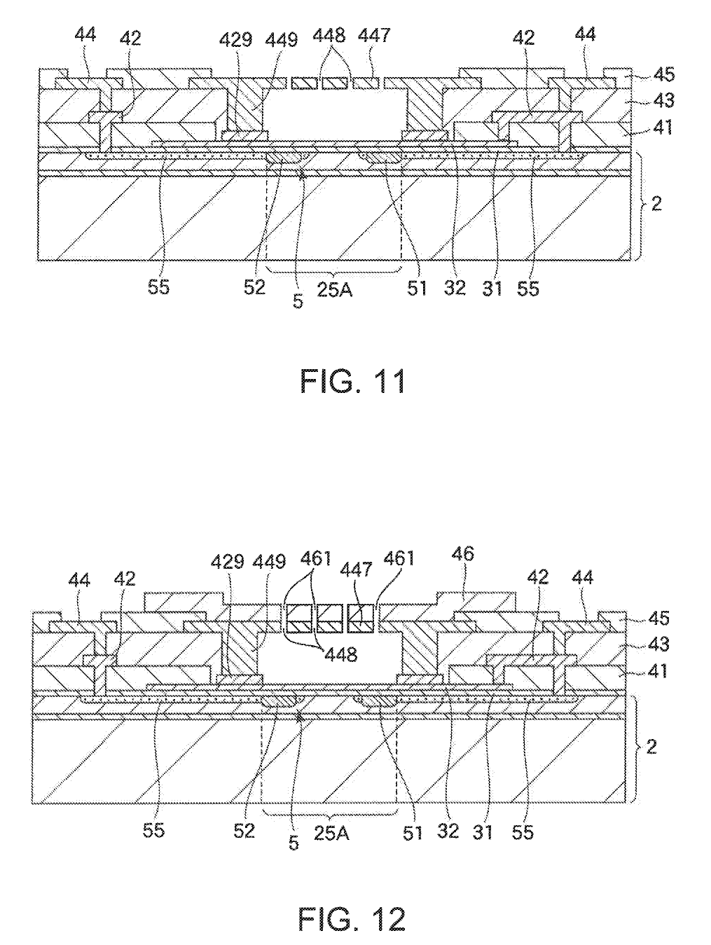

Then, the semiconductor substrate 2 is exposed to an etching solution of e.g. buffered hydrofluoric acid. Thereby, as shown in FIG. 11, parts of the interlayer insulating films 41, 43 (the parts surrounded by the guard rings 429, 449) are removed via the through holes 448. In this regard, the guard rings 429, 449 formed by the aluminum films function as etching stoppers.

Then, as shown in FIG. 12, the covering layer 46 is formed on the upper surfaces of the wiring layer 44 and the surface protective film 45 using sputtering, CVD, or the like. Note that, in the embodiment, the covering layer 46 is formed by the silicon film. At the step, the covering layer 46 is deposited not to completely close the through holes 448 of the ceiling portion 447, and thereby, the covering layer 46 having the through holes 461 communicating with the through holes 448 is obtained.

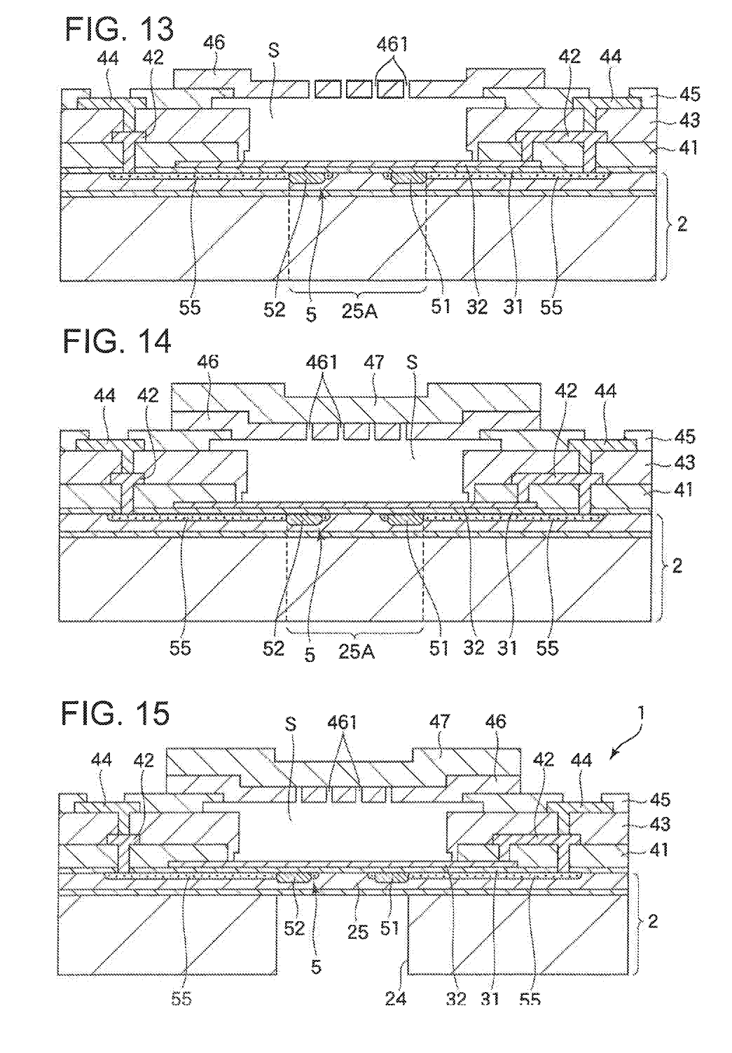

Then, the semiconductor substrate 2 is exposed to an etching solution of e.g. mixed acid of phosphoric acid, acetic acid, and nitric acid. Thereby, the wiring layers 42, 44 (guard rings 429, 449 and ceiling portion 447) are removed via the through holes 461. Thereby, as shown in FIG. 13, the pressure reference chamber S is formed.

Then, as shown in FIG. 14, the pressure reference chamber S is set in the vacuum state and the sealing layer 47 is deposited on the covering layer 46 using sputtering, CVD, or the like and the through holes 461 are sealed. Thereby, the pressure reference chamber S sealed in the vacuum state is obtained.

### Diaphragm Formation Step

Then, as shown in FIG. 15, the first silicon layer 21 is etched using e.g. dry etching (particularly, silicon deep etching), the recessed portion 24 opening to the lower surface of the semiconductor substrate 2 is formed, and thereby, the diaphragm 25 is obtained. Note that the order of the diaphragm formation step is not particularly limited, but the step may be performed next to the preparation step, for example.

In the above described manner, the pressure sensor 1 is obtained. According to the manufacturing method, the pressure sensor 1 may be easily formed.

### Second Embodiment

Next, a pressure sensor according to the second embodiment of the invention will be explained.

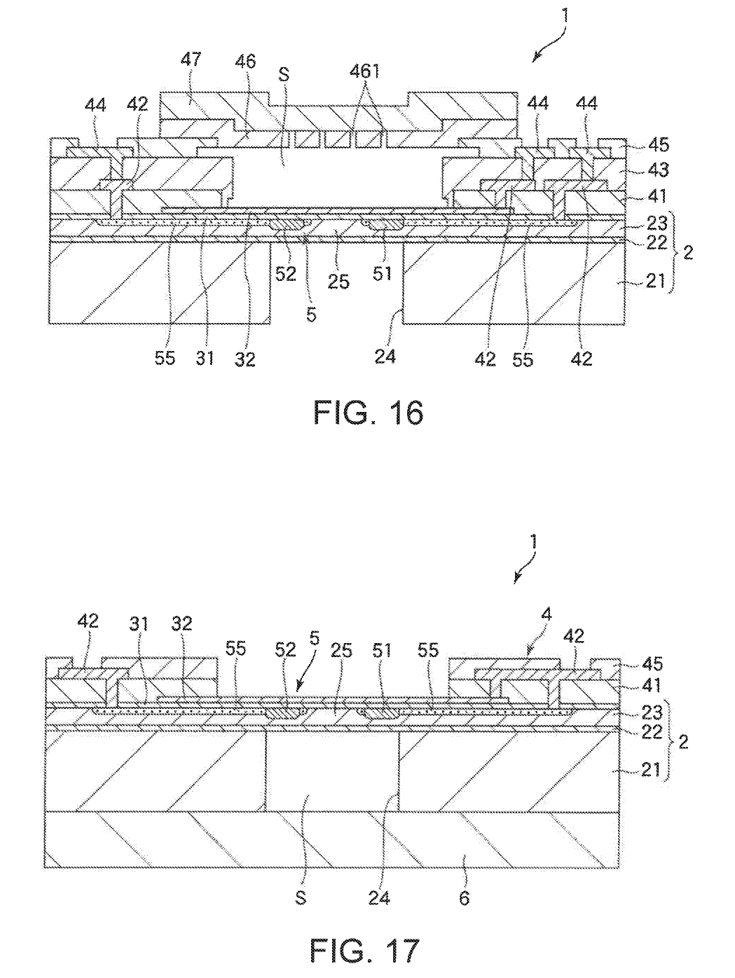

FIG. 16 is a sectional view of the pressure sensor according to the second embodiment of the invention.

The pressure sensor 1 according to the embodiment is the same as the above described pressure sensor of the first embodiment except that the sensor part 5 and the conducting layer 32 are not electrically connected.

As below, the pressure sensor of the second embodiment will be explained with a focus on differences from the above described first embodiment, and the explanation of the same items will be omitted. The same configurations as those of the above described embodiment have the same signs.

As shown in FIG. 16, in the pressure sensor 1 of the embodiment, the sensor part 5 and the conducting layer 32 are not connected via the wiring layers 42, 44. The sensor part 5 is electrically connected to the drive circuit 59 and the conducting layer 32 is electrically connected to a power supply circuit (not shown). Further, a voltage equal to or larger than the drive voltage AVDC applied from the drive circuit 59 to the sensor part 5 is applied from the power supply circuit to the conducting layer 32.

Here, the configuration of the power supply circuit is not particularly limited, but may have an amplifier circuit that amplifies the drive voltage AVDC from the drive circuit 59 and apply the amplified voltage to the conducting layer 32, for example.

As described above, the pressure sensor 1 of the embodiment includes the semiconductor substrate 2 having the diaphragm 25 that flexurally deforms by pressurization, the sensor part 5 provided in the diaphragm 25, to which the drive voltage AVDC is applied, the insulating layer 31 provided on the diaphragm 25, and the conducting layer 32 provided on the insulating layer 31. Further, the conducting layer 32 is set at the same potential as the drive voltage AVDC applied to the sensor part 5 or the potential larger than the drive voltage AVDC. Thereby, as described above, formation of an inversion layer in the semiconductor substrate 2 may be suppressed and short circuit of the sensor part 5 may be suppressed. Accordingly, the thickness of the insulating layer 31 may be reduced, and the diaphragm 25 easily flexes by the amount of reduction and the sensor sensitivity is improved.

According to the second embodiment, the same advantages as those of the above described first embodiment may be offered.

### Third Embodiment

Next, a pressure sensor according to the third embodiment of the invention will be explained.

FIG. 17 is a sectional view of the pressure sensor according to the third embodiment of the invention.

The pressure sensor according to the embodiment is the same as the above described pressure sensor of the first embodiment except that the placement of the pressure reference chamber S is different.

As below, the pressure sensor according to the third embodiment will be explained with a focus on differences from the above described first embodiment, and the explanation of the same items will be omitted. The same configurations as those of the above described embodiments have the same signs.

As shown in FIG. 17, the pressure sensor 1 of the embodiment has a base substrate 6 joined to the lower surface of the semiconductor substrate 2 and air-tightly sealing the recessed portion 24 in place of a part of the surrounding structure 4 omitted from the above described first embodiment. In the pressure sensor 1 having the configuration, the pressure reference chamber S is placed between the diaphragm 25 and the base substrate 6. That is, the pressure sensor 1 of the embodiment has the pressure reference chamber S located on the opposite side to the conducting layer 32 of the diaphragm 25. The pressure reference chamber S is an airtight space and the pressure within the pressure reference chamber S is a reference value of pressure detected by the pressure sensor 1. Accordingly, the pressure on the diaphragm 25 may be detected more accurately.

As the base substrate 6, e.g. a silicon substrate, glass substrate, ceramic substrate, or the like may be used. Note that the base substrate 6 is sufficiently thick compared to the diaphragm 25 so that the portion facing the diaphragm 25 via the pressure reference chamber S may not be deformed by the differential pressure (the difference between the pressure of the pressure reference chamber S and the environmental pressure).

According to the third embodiment, the same advantages as those of the above described first embodiment may be offered.

### Fourth Embodiment

Next, a pressure sensor according to the fourth embodiment of the invention will be explained.

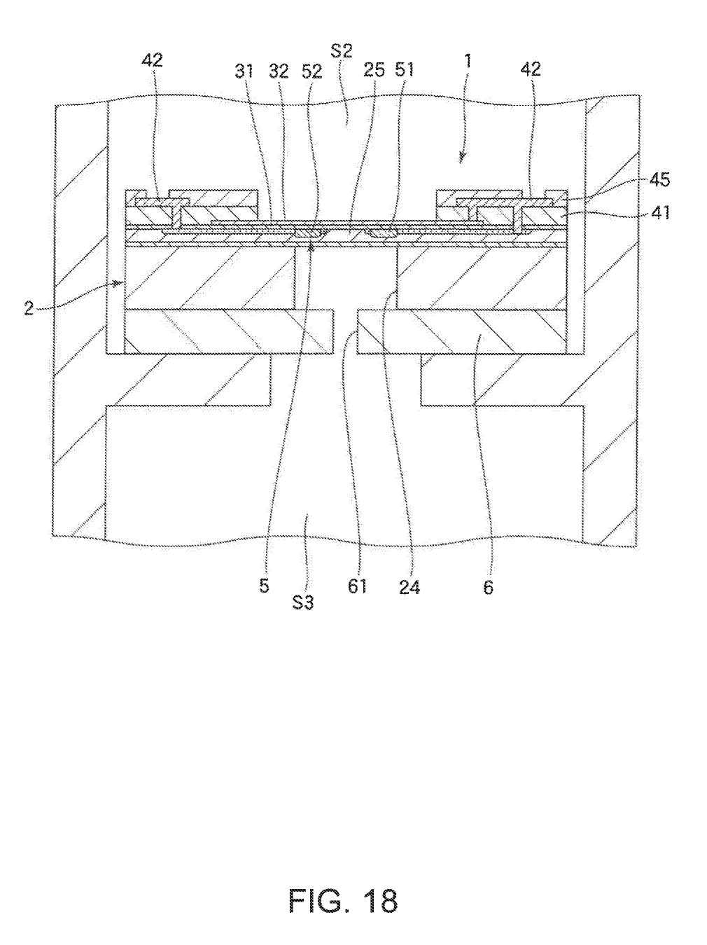

FIG. 18 is a sectional view of a pressure sensor according to the fourth embodiment of the invention.

As below, the pressure sensor according to the fourth embodiment will be explained with a focus on differences from the above described embodiments, and the explanation of the same items will be omitted.

The pressure sensor according to the fourth embodiment of the invention is the same as the above described third embodiment except that the pressure reference chamber S is not provided. The same configurations as those of the above described embodiments have the same signs.

As shown in FIG. 18, in the pressure sensor 1 of the embodiment, a through hole 61 communicating with the recessed portion 24 is formed in the base substrate 6. The pressure sensor 1 of the embodiment is provided so that the upper surface and the lower surface of the diaphragm 25 may be located in different spaces from each other. Specifically, the upper surface of the diaphragm 25 is located in a space S2 and the lower surface of the diaphragm 25 is located in a space S3. According to the configuration, the pressure difference between the space S2 and the space S3 may be detected by the pressure sensor 1. That is, the pressure sensor 1 may be used as a differential pressure sensor.

According to the fourth embodiment, the same advantages as those of the above described first embodiment may be offered.

### Fifth Embodiment

Next, a pressure sensor module according to the fifth embodiment of the invention will be explained.

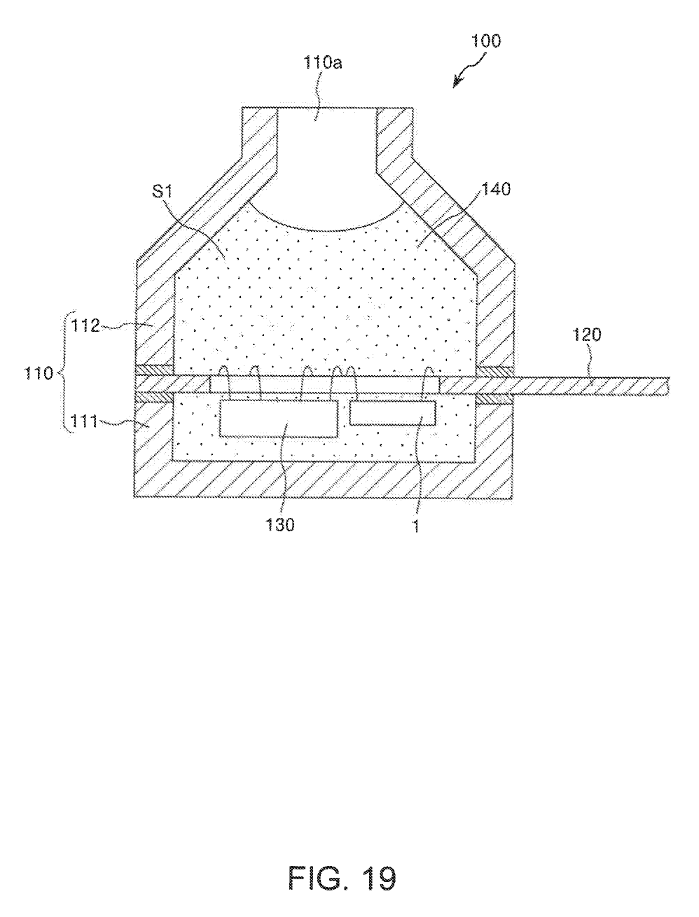

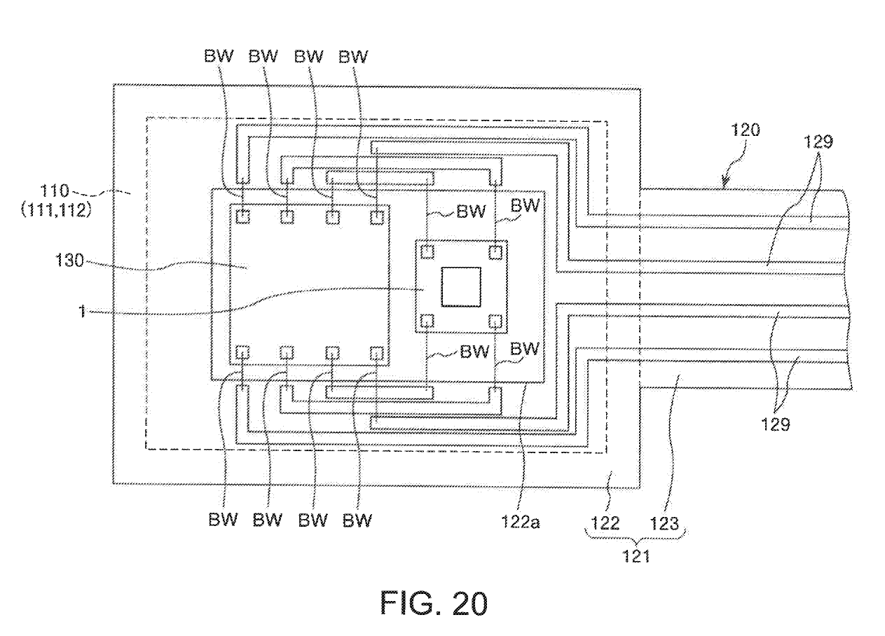

FIG. 19 is a sectional view of the pressure sensor module according to the fifth embodiment of the invention. FIG. 20 is a plan view of a supporting substrate of the pressure sensor module shown in FIG. 19.

As below, the pressure sensor module of the fifth embodiment will be explained with a focus on differences from the above described embodiments, and the explanation of the same items will be omitted.

As shown in FIG. 19, a pressure sensor module 100 includes a package 110 having an internal space S1, a supporting substrate 120 provided to protrude outside of the package 110 from the internal space S1, a circuit element 130 and the pressure sensor 1 supported by the supporting substrate 120 within the internal space S1, and a filled portion 140 provided in the internal space S1. According to the pressure sensor module 100, the pressure sensor 1 may be protected by the package 110 and the filled portion 140. Note that, as the pressure sensor 1, for example, any one of the pressure sensors of the above described first, second, third embodiments may be used.

The package 110 has a base 111 and a housing 112 and the base 111 and the housing 112 are joined to each other via an adhesive layer with the supporting substrate 120 in between. Thus formed package 110 has an opening 110a formed in the upper end portion thereof and the internal space S1 communicating with the opening 110a.

The constituent materials of the base 111 and the housing 112 are not particularly limited, but include e.g. insulating materials of various ceramics such as oxide ceramics including alumina, silica, titania, zirconia and nitride ceramics including silicon nitride, aluminum nitride, titanium nitride, and various resin materials such as polyethylene, polyamide, polyimide, polycarbonate, acrylic resin, ABS resin, and epoxy resin, and one or two or more kinds of the materials may be combined for use. Among them, various ceramics may be used particularly preferably.

As above, the package 110 is explained, however, the configuration of the package 110 is not particularly limited as long as the configuration may fulfill the function.

The supporting substrate 120 is sandwiched between the base 111 and the housing 112, and provided to protrude outside of the package 110 from the internal space S1. Further, the supporting substrate 120 supports the circuit element 130 and the pressure sensor 1 and electrically connects the circuit element 130 and the pressure sensor 1. As shown in FIG. 20, the supporting substrate 120 includes a base member 121 having flexibility, and a plurality of wires 129 provided on the base member 121.

The base member 121 has a base portion 122 in a frame shape with an opening 122a and a strip portion 123 in a strip shape extending from the base portion 122. The strip portion 123 is sandwiched by the base 111 and the housing 112 in the outer edge portion of the base portion 122 and extends to the outside of the package 110. As the base member 121, e.g. a generally-used flexible printed board may be used. Note that, in the embodiment, the base member 121 has flexibility, however, all or part of the base member 121 may be hard.

In the plan view of the base member 121, the circuit element 130 and the pressure sensor 1 are located inside of the opening 122a and arranged side by side. Further, the circuit element 130 and the pressure sensor 1 are respectively hung from the base member 121 via bonding wires BW and supported by the supporting substrate 120 in a suspended state from the supporting substrate 120. Furthermore, the circuit element 130 and the pressure sensor 1 are respectively electrically connected via the bonding wires BW and the wires 129. As described above, the circuit element 130 and the pressure sensor 1 are supported by the supporting substrate 120 in the suspended state from the supporting substrate 120, and thereby, stress is harder to transmit from the supporting substrate 120 to the circuit element 130 and the pressure sensor 1 and pressure sensing accuracy of the pressure sensor 1 is improved.

The circuit element 130 has a drive circuit that supplies a voltage to the bridge circuit 50, a temperature-compensated circuit for temperature compensation of the output from the bridge circuit 50, a pressure detection circuit that obtains the applied pressure from the output from the temperature-compensated circuit, an output circuit that converts and outputs the output from the pressure detection circuit in a predetermined output format (CMOS, LV-PECL, LVDS, or the like), etc.

The filled portion 140 is provided in the internal space S1 to cover the circuit element 130 and the pressure sensor 1. By the filled portion 140, the circuit element 130 and the pressure sensor 1 may be protected (from dust and water) and external stress acting on the pressure sensor 1 (e.g. drop impact) is harder to transmit to the circuit element 130 and the pressure sensor 1.

Further, the filled portion 140 may be formed using a liquid or gelled filler. It is particularly preferable that the portion is formed using the gelled filler so that excessive displacement of the circuit element 130 and the pressure sensor 1 may be suppressed. According to the filled portion 140, the circuit element 130 and the pressure sensor 1 may be effectively protected from moisture and pressure may be efficiently transmitted to the pressure sensor 1. The filler forming the filled portion 140 is not particularly limited, but e.g. silicone oil, fluorine-based oil, silicone gel, or the like may be used.

As above, the pressure sensor module 100 is explained. The pressure sensor module 100 has the pressure sensor 1 and the package 110 housing the pressure sensor 1. Accordingly, the pressure sensor 1 may be protected by the package 110. Further, the module may enjoy the above described advantages of the pressure sensor 1 and exert excellent reliability.

Note that the configuration of the pressure sensor module 100 is not limited to the above described configuration, but the filled portion 140 may be omitted, for example. Further, in the embodiment, the pressure sensor 1 and the circuit element 130 are supported by the bonding wires BW in the suspended state by the supporting substrate 120, however, for example, the pressure sensor 1 and the circuit element 130 may be placed directly on the supporting substrate 120. Furthermore, in the embodiment, the pressure sensor 1 and the circuit element 130 are arranged side by side, however, for example, the pressure sensor 1 and the circuit element 130 may be arranged to overlap in the height direction.

### Sixth Embodiment

Next, an electronic apparatus according to the sixth embodiment of the invention will be explained.

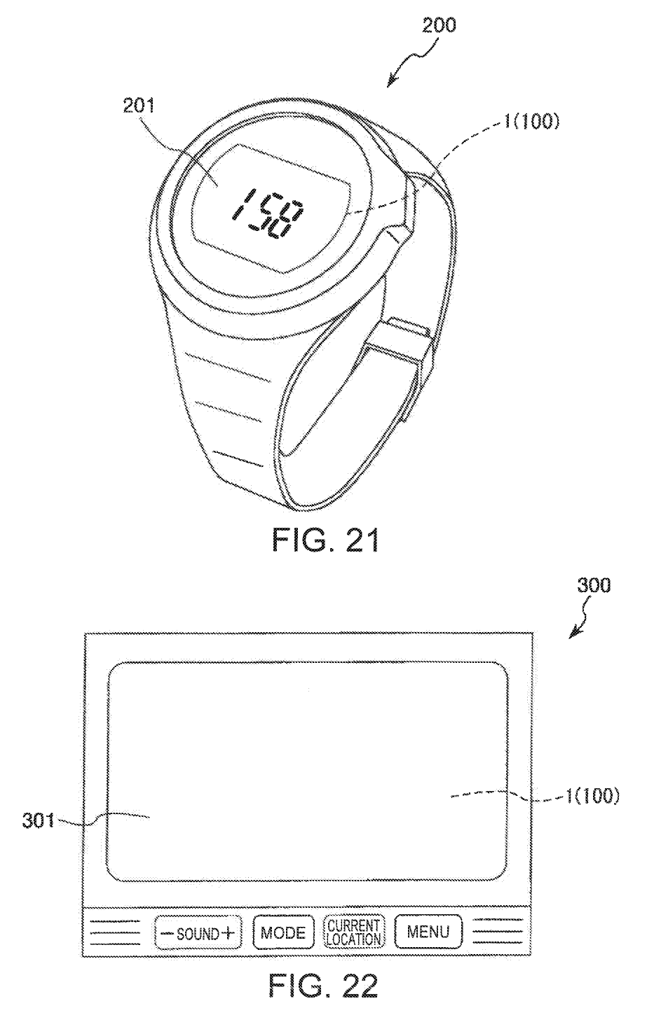

FIG. 21 is a perspective view showing an altimeter as the electronic apparatus according to the sixth embodiment of the invention.

As shown in FIG. 21, an altimeter 200 as an electronic apparatus may be worn on a wrist like a wristwatch. The altimeter 200 has the pressure sensor 1 (pressure sensor module 100) mounted inside, and may display the altitude of the current location above the sea level, the atmospheric pressure in the current location, etc. on a display part 201. In the display part 201, various kinds of information including the current time, the heart rate of the user, the weather, etc. may be displayed.

The altimeter 200 as an example of the electronic apparatus has the pressure sensor 1. Accordingly, the altimeter 200 may enjoy the above described advantages of the pressure sensor 1 and exert higher reliability.

### Seventh Embodiment

Next, an electronic apparatus according to the seventh embodiment of the invention will be explained.

FIG. 22 is a front view showing a navigation system as the electronic apparatus according to the seventh embodiment of the invention.

As shown in FIG. 22, a navigation system 300 as an electronic apparatus includes map information (not shown), position information acquisition means from GPS (Global Positioning System), self-contained navigation means using a gyro sensor, an acceleration sensor, and vehicle velocity data, the pressure sensor 1 (pressure sensor module 100), and a display part 301 that displays predetermined position information or route information.

According to the navigation system 300, in addition to the acquired position information, altitude information may be acquired. For example, in the case of traveling on an elevated road showing nearly the same position as that of a general road in the position information, it is impossible for a navigation system without the altitude information to determine whether traveling on the general road or traveling on the elevated road, and information of the general road is provided as priority information to the user. Accordingly, the pressure sensor 1 is mounted on the navigation system 300 and the altitude information is acquired by the pressure sensor 1, and thereby, an altitude change by entry from a general road to an elevated road may be detected and navigation information in the traveling state on the elevated road may be provided to the user.

The navigation system 300 as an example of the electronic apparatus has the pressure sensor 1. Accordingly, the navigation system 300 may enjoy the above described advantages of the pressure sensor 1 and exert higher reliability.

Note that the electronic apparatus according to the invention is not limited to the above described altimeter and navigation system, but may be applied to e.g. a personal computer, digital still camera, cell phone, smartphone, tablet terminal, watch (including smartwatch), drone, medical device (e.g. electronic thermometer, sphygmomanometer, blood glucose meter, electrocardiographic measurement system, ultrasonic diagnostic system, or electronic endoscope), various measuring instruments, meters and gauges (e.g. meters for vehicles, airplanes, and ships), flight simulator, or the like.

### Eighth Embodiment

Next, a vehicle according to the eighth embodiment of the invention will be explained.

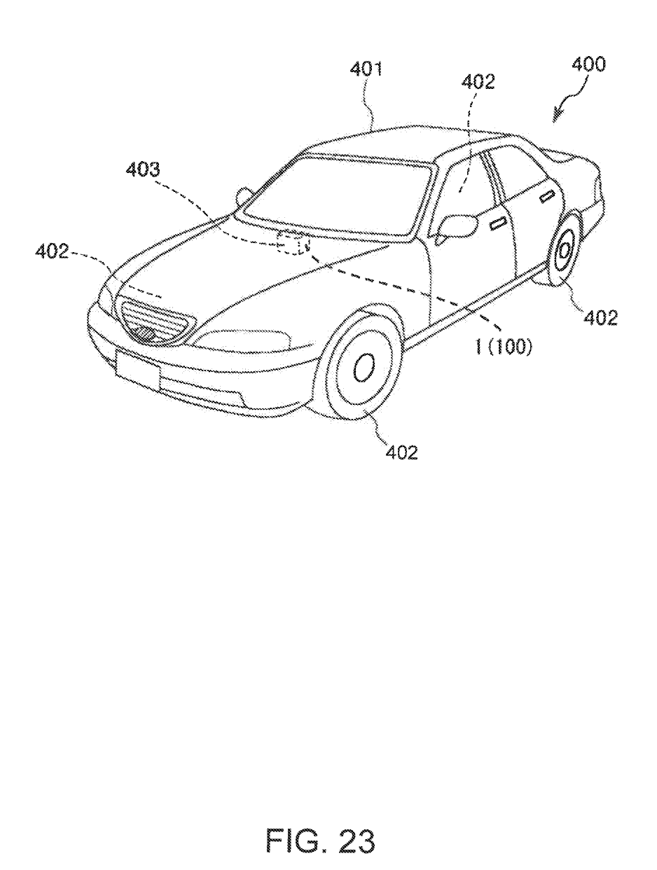

FIG. 23 is a perspective view showing an automobile as the vehicle according to the eighth embodiment of the invention.

As shown in FIG. 23, an automobile 400 as a vehicle has a vehicle body 401 and four wheels 402 (tires), and is adapted to turn the wheels 402 by a power source (engine) (not shown) provided in the vehicle body 401. The automobile 400 has an electronic control unit (ECU) 403 mounted on the vehicle body 401 and the electronic control unit 403 contains the pressure sensor 1. The pressure sensor 1 detects an acceleration, inclination, or the like of the vehicle body 401, and thereby, the electronic control unit 403 grasps the traveling state, attitude, etc. and may properly control the wheels 402 etc. Thereby, the automobile 400 may travel safely and stably. Note that the pressure sensor 1 may be mounted on a navigation system provided in the automobile 400 or the like.

The automobile 400 as an example of the vehicle has the pressure sensor 1. Accordingly, the automobile 400 may enjoy the above described advantages of the pressure sensor 1 and exert higher reliability.

As above, the pressure sensor, pressure sensor module, electronic apparatus, and vehicle are explained based on the respective illustrated embodiments, however, the invention is not limited to those. The configurations of the respective parts may be replaced by arbitrary configurations having the same functions. Further, other arbitrary configurations and steps may be added thereto. Furthermore, the respective embodiments may be appropriately combined.

The entire disclosure of Japanese Patent Application No. 2016-252803, filed Dec. 27, 2016 is expressly incorporated by reference herein.

What is claimed is:

1. A pressure sensor comprising:
a semiconductor substrate having a diaphragm that flexurally deforms by pressurization;
a sensor part provided in the diaphragm, to which a drive voltage is applied;
an insulating layer provided on the diaphragm;
a conducting layer provided on the insulating layer; and
a drive circuit that supplies a predetermined potential so that the drive voltage may be applied to the sensor part,
wherein the conducting layer is set at a same potential as the predetermined potential or a potential larger than the predetermined potential.

2. The pressure sensor according to claim 1, wherein the semiconductor substrate contains silicon.

3. The pressure sensor according to claim 1, wherein the conducting layer is electrically connected to the sensor part.

4. The pressure sensor according to claim 1, wherein the conducting layer contains polysilicon.

5. The pressure sensor according to claim 1, wherein a thickness of the conducting layer is equal to or smaller than 50 nm.

6. The pressure sensor according to claim 1, wherein the insulating layer contains silicon oxide.

7. The pressure sensor according to claim 1, wherein a thickness of the insulating layer is equal to or smaller than 400 nm.

8. The pressure sensor according to claim 1, further comprising a pressure reference chamber located on the conducting layer side of the diaphragm.

9. The pressure sensor according to claim 1, further comprising a pressure reference chamber located on an opposite side to the conducting layer of the diaphragm.

10. A pressure sensor module comprising:
the pressure sensor according to claim 1; and
a package housing the pressure sensor.

11. An electronic apparatus comprising the pressure sensor according to claim 1.

12. A vehicle comprising the pressure sensor according to claim 1.
